(19) United States
(12) Patent Application Publication
(10) Pub. No.: US 2011/0018649 A1
(43) Pub. Date: Jan. 27, 2011

(54) ELECTRICAL RESONATOR DEVICE WITH A WIDE FREQUENCY VARIATION RANGE

(75) Inventors: Jean-Baptiste David, Grenoble (FR); Pierre Vincent, Villard de Lans (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: COMMISSAR.A L'ENERG.ATOM.ET AUX ENERG. ALTERN., PARIS (FR)

(21) Appl. No.: 12/812,559

(22) PCT Filed: Jan. 16, 2009
(86) PCT No.: PCT/EP2009/050495

§ 371 Date: Oct. 11, 2010

Related U.S. Application Data
(60) Provisional application No. 61/035,437, filed on Mar. 11, 2008.

(30) Foreign Application Priority Data
Jan. 18, 2008 (FR) 0850327

(51) Int. Cl. H03B 5/32; H01L 41/107; H01L 41/04; H03H 9/15

(52) U.S. Cl. 331/158; 310/318; 310/313 R; 333/187

(57) ABSTRACT

An electrical resonator device, capable of operating at variable frequency ω, including: an acoustic wave resonator, a first electrical circuit coupled in parallel to the resonator with an adjustable complex impedance whose imaginary part is equal to

$$\frac{- j}{{C}_{1} ω} ,$$

where C₁≧0, a second electrical circuit coupled in parallel to the resonator and the first electrical circuit, with a complex impedance whose imaginary part is equal to

$$\frac{- j}{{C}_{2} ω} ,$$

where C₂<0, ω is the operating frequency of the device.

This application is related to and claims priority of U.S. provisional patent application No. 61/035,437, filed Mar. 11, 2008, which is incorporated herein by reference for all purposes. This application also claims priority of French patent application no 08 50327, filed Jan. 18, 2008, which is incorporated herein by reference for all purposes.

### TECHNICAL FIELD

This document relates to an electrical resonator device with a wide tuning range, or variation range, of frequencies, used for example to generate a frequency and noise stabilised reference source, thus creating a voltage controlled oscillator (VCO). Such a VCO may for example be used for the transmission and reception chains of mobile communications terminals. This document also applies to the creation of selective filters with wide frequency bands, which also have applications in mobile communication systems.

### BACKGROUND

In general, a VCO is characterised by four parameters:
phase noise: this characterises the spectral purity of the oscillator. The intrinsic vibration of the oscillator is quantified in the form of a spectral noise density, which decreases when moved away from its fundamental frequency. The level of this spectral density, expressed in dBc/Hz, is provided at a certain frequency difference with respect to the fundamental frequency. Good phase noise ensures good reception sensitivity, as well as good modulation quality.
Frequency variation range: this is the capacity of the oscillator to tune into a given frequency band. In general, the oscillator is expected to cover all of the frequency bands corresponding to the standard for which the system has been created. In a context of multi-standard systems, of which the frequency bands are close to one another, a large frequency variation range is an advantage.
Output power rating: this is the power level of the reference signal produced by the oscillator. The higher its level, the more efficient its phase noise, and the simpler it is to interface it with the other blocks of the system.
Consumption: this is the continuous power that the VCO needs to operate. It is connected to the DC voltage available in the system. With the densification of technology, supply voltages are being reduced, which considerably restricts the capacity of the oscillator to provide power.

The optimisation of these four parameters is generally based on several compromises. Consequently, the improvement of the phase noise of the VCO is made to the detriment of the frequency variation range and the consumption. Furthermore, a high output power level increases the consumption of the VCO. In general, a VCO has optimised performances based around one or more of these constraints, depending on the specific features of the transmission/reception system for which it has been designed. In order to compare the performances of the VCO, there is a mathematical indicator which links the various constraints: figure of merit. The higher it is, the more the VCO may be considered as efficient.

To make a VCO, a resonator, for example modelled by an RLC circuit (resistor+inductance+capacitor) connected in series or in parallel to a negative electrical resistor, is associated to an additional complex impedance element which modifies the resonance conditions of the VCO to suit a command. By negative electrical resistor it is meant an electrical component whose behaviour, at least within a certain range, is such that the current which passes through it drops when the voltage applied to its terminals increases. The complex impedance element is for example a variable electrical capacity, obtained for example with a varicap diode, or a variable inductive element. The phase noise of the VCO thus created depends at the first order on the association of the quality coefficients of the resonator and the variable complex impedance element, then at the second order on the noise specific to the transistors used to create the negative resistor of the resonator.

In order to improve the stability of the oscillator of a VCO in an RF system, especially a digital one, a technique is to make integrated VCOs featuring a BAW resonator (Bulk Acoustic Waves), for example of the FBAR type (Film Bulk Acoustic Resonator), or a SAW resonator (Surface Acoustic Waves) associated to a variable complex impedance element whose voltage can be controlled. It is thus possible to satisfy high constraints of stability, phase noise, and power consumption, especially at high operating frequencies, compatible with current mobile communication systems.

Resonators with high quality coefficients such as BAW or SAW have an impedance which has a remarkable value at two frequencies close to one another: the series resonance frequency, for which the impedance of the resonator is the lowest, and the anti-resonance frequency, for which the impedance of the resonator is the highest. The variable complex impedance element of a VCO featuring a BAW or SAW resonator permits the resonance or anti-resonance frequency of the VCO to be varied.

In mobile communication systems, the classic frequency variation ranges of the VCOs reaches approximately 5%. Furthermore, maintaining a good quality coefficient is primordial, as it is involved firstly in the phase noise of the function. The publication “Novel VCO Architecture Using Series Above-IC FBAR and Parallel LC Resonance” by K. B. Östman et al., IEEE J. Solid-State Circuits, vol. 41, no 10, October 2006, describes a VCO featuring a BAW resonator. Even though this circuit has an excellent phase noise, and an acceptable frequency variation range, it has high consumption due to the increase in resistive losses in series resulting from the addition of series elements to the BAW resonator.

Moreover, a figure of merit of such a VCO is limited by the intrinsic properties of the BAW resonator, which considerably restricts the frequency variation range of the VCO. For example, for the UMTS standard which uses a frequency band of 60 MHz to 2.14 GHZ in reception, no integrated VCO operating with a high quality coefficient resonator can satisfy the frequency variation range constraints for digital mobile communication systems that use such wide frequency bands. The integrated VCOs for these applications thus currently operate with the aid of integrated resonators with quality coefficients of less than 10.

High quality coefficient resonators of the BAW or SAW type are also used to create filters in multi-standard transmission and/or reception architectures for mobile communication devices. These filters are for example made from one or several coupled resonators, wherein this coupling may be made in series and/or in parallel to obtain Ladder filters or Lattice filters.

However, these filters have difficulties in covering the required frequency ranges, especially for mobile communication systems.

### DESCRIPTION OF THE INVENTION

Thus there is a need to propose an electrical resonator device that does not have the disadvantages of the prior art, which is to say that it has a good quality coefficient thanks to a high quality coefficient resonator, whilst offering a wide frequency variation range.

To achieve this, one embodiment proposes an electrical resonator device, capable of operating at a variable frequency ω or operating at a variable frequency ω, comprising at least:
an acoustic wave resonator,
a first electrical circuit coupled in parallel to the resonator with a positive and adjustable electrical capacity,
a second electrical circuit coupled in parallel to the resonator and to the first electrical circuit with a strictly negative electrical capacity.

One embodiment also proposes an electrical resonator device, capable of operating at a variable frequency ω or operating at a variable frequency ω, comprising at least:
an acoustic wave resonator,
a first electrical circuit coupled in parallel to the resonator with an adjustable complex impedance whose imaginary part is equal to

$$\frac{- j}{{C}_{1} ω} ,$$

where C₁≧0,
a second electrical circuit coupled in parallel to the resonator and the first electrical circuit, with a complex impedance whose imaginary part is equal to

$$\frac{- j}{{C}_{2} ω} ,$$

where C₂<0,

ω is the resonance frequency, or operating frequency, of the device.

ω corresponds to the operating frequency of the electrical device. For example, when the electrical resonator device is a voltage controlled oscillator, the value of the operating frequency depends on the value of the control voltage applied to the oscillator.

Thus, thanks to the second electrical circuit with a strictly negative electrical capacity and a capacitive behaviour, whatever the operating frequency of the device, the anti-resonance frequency of the device is moved to a frequency that is higher than the natural anti-resonance frequency of the acoustic wave resonator, without changing its series resonance frequency. In other words, it is possible to increase the electromechanical coupling of the acoustic wave resonator, and thus increase the frequency variation range of the device. Thus the device is functional on a wide frequency range.

According to this embodiment, it is possible to create an oscillating arrangement, for example a voltage controlled oscillator or a filter, with a series resonance frequency and an anti-resonance frequency, comprising an acoustic wave resonator, an electronic function with a complex impedance whose real part may be negative and whose imaginary part is equivalent to a negative electrical capacity, and a positive variable electrical capacity. This oscillating arrangement permits for example a voltage controlled oscillator to be created whose phase noise is mainly determined by the high quality of the acoustic wave resonator, and whose frequency variation range is significantly higher than the variation range obtained with a resonator such as an RLC resonator. This oscillating arrangement also permits a filter to be created which filters a wider band of frequencies than the known filters, without degrading the insertion losses and the rejection of the filter.

The presence of the complex impedance of which the imaginary part is equal to

$$\frac{- j}{{C}_{2} ω} ,$$

where C₂<0, or the electrical capacity negative, coupled to the acoustic wave resonator increases the frequency variation range of the device by a factor of between approximately 4 and 5 with respect to the known devices, for example VCOs.

Furthermore, this embodiment permits a VCO to be obtained that has a wide frequency tuning range with a low phase noise, and benefits from the quality coefficient of the variable electrical capacity increased by the quality coefficient of the acoustic wave resonator coupled in parallel, wherein the tuning frequency may correspond to the anti-resonance frequency of the VCO.

Finally, by operating at the anti-resonance frequency, the VCO thus created maintains a low consumption, while maintaining a low phase noise.

The electrical device, and particularly the second electrical circuit, may be made with small size components, thus enabling to realize an electrical device, such a VCO, which is fully integrated, e.g. realized with microelectronic technologies, i.e. which has a micrometric size.

The second electrical circuit has a capacitive behaviour, whatever the operating frequency of the device. Indeed, contrary to an impedance of a positive inductance which has a positive imaginary part and turns according to the clockwise direction, when it is drawn on a Smith abacus during an increase of the operating frequency, an impedance of a negative electrical capacity has a positive imaginary part but turns according to the counter clockwise direction, when it is drawn on a Smith abacus during an increase of the operating frequency.

Although, for a given operating frequency, a positive inductance value exists such that the location (on a Smith abacus) of the impedance corresponds to the location of the impedance of an negative electrical capacity, the restrictions to obtain this inductance are much more important than to obtain the corresponding negative electrical capacity. For example, for a low operating frequency, e.g. equals to around 100 MHz, an electrical capacity of −1 pF has impedance corresponding to the impedance of an inductance of 2.5 pH, which cannot be realized in an integrated manner.

Moreover, the derivative of an impedance of a negative electrical capacity is different of the one of an inductance.

Contrary to an inductance, the second electrical circuit, with a complex impedance whose imaginary part is equal to

$$\frac{- j}{{C}_{2} ω} ,$$

where C₂<0, that is with a negative electrical capacity, enables:
not short-circuiting the acoustic wave resonator during a low frequency operation of the device and thus keeping the component property to be opposed to the direct current circulation;
to present a good figure of merit.

The second electrical circuit may further have a strictly negative electrical resistor.

The complex impedance of the second electrical circuit may comprise a real part whose value is strictly negative.

The second electrical circuit may comprise a plurality of field effect transistors coupled to an inductive component.

The first electrical circuit may comprise at least one diode of the varicap type or at least one switched capacity.

The resonator may be of the volume acoustic wave or surface acoustic wave type.

The device may further comprise a third electrical circuit coupled in parallel to the resonator, to the first and second electrical circuits, and have a negative electrical resistor or a complex impedance whose real part has a strictly negative value.

The third electrical circuit may comprise at least one differential pair formed by at least two field effect transistors.

This document also relates to a voltage controlled oscillator (VCO) comprising at least one device such as that described above.

This document also relates to an electronic filter featuring at least one device such as that described previously.

### BRIEF DESCRIPTION OF THE DRAWINGS

The invention will be better understood after reading the description of embodiments provided purely by way of illustration and in no way restrictively, in reference to the appended drawings among which:

FIG. 1 represents a voltage controlled oscillator according to one specific embodiment;

FIG. 2 represents an embodiment of the second electrical circuit of a voltage controlled oscillator;

FIG. 3 represents an equivalent electrical circuit of the second electrical circuit shown in FIG. 2;

FIG. 4 represents an equivalent circuit, modelled firstly, of an acoustic resonator used by a voltage controlled oscillator;

FIG. 5 represents graphs of the evolution of the impedance of an acoustic resonator according to the frequency of the resonator, coupled or not with an electrical circuit with a complex impedance whose imaginary part is equal to

$$\frac{- j}{{C}_{2} ω} ,$$

where C₂<0.

Identical, similar or equivalent parts of the different figures described below bear the same numerical references so as to facilitate the passage from one figure to another.

The different parts shown in the figures are not necessarily to a uniform scale, in order to make the figures easier to read.

It should be understood that the different possibilities (variants and embodiments) are not exclusive from one another and may be combined.

### DETAILED DESCRIPTION OF SPECIFIC EMBODIMENTS

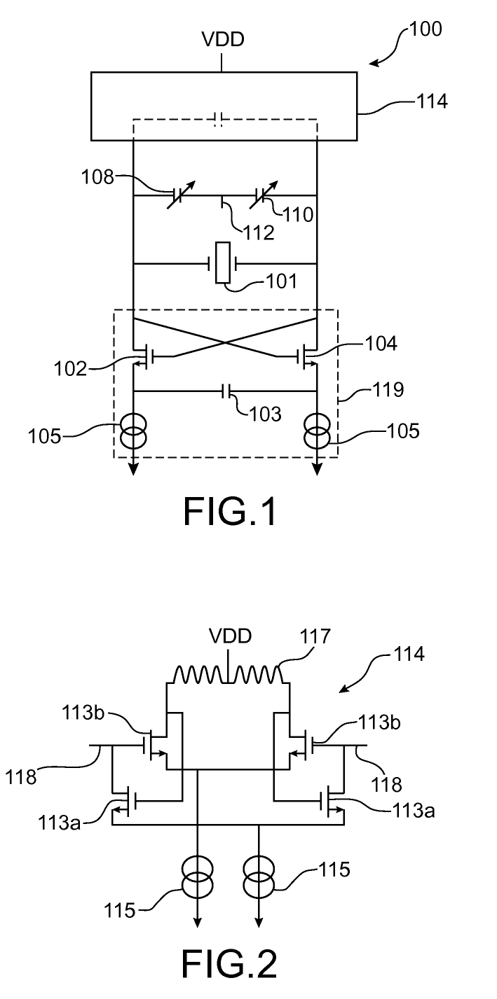

Firstly in reference to FIG. 1, which represents one example of a voltage controlled oscillator (VCO) 100 according to one specific embodiment.

The VCO 100 features a resonator 101 with a high quality coefficient (for example between approximately 500 and 1500). In the embodiment described in relation to FIG. 1, the resonator 101 is of the Bulk Acoustic Wave type (BAW).

The VCO 100 further comprises a first electrical circuit, with a positive variable electrical capacity, which is to say with an adjustable complex impedance whose imaginary part is equal to

$$\frac{- j}{{C}_{1} ω} ,$$

where C₁≧0 and ω is the resonance frequency of the VCO 100, i.e. the operating frequency of the VCO 100. This first electrical circuit is here formed by a pair of diodes 108, 110 of the varactor or varicap type, coupled in series with respect to one another. This first electrical circuit is coupled in parallel to the resonator 101. A command input 112 positioned between the two diodes 108, 110 allows a command voltage to be applied to the two diodes 108, 110, wherein the value of the electrical capacity, which is to say the value of the imaginary part of the complex impedance presented by the two diodes 108, 110, is defined according to the value of this command voltage.

The VCO 100 also comprises a second electrical circuit 114 with a strictly negative electrical capacity, which is to say with a complex impedance whose imaginary part is equal to

$$\frac{- j}{{C}_{2} ω} ,$$

where C₂<0. This second electrical circuit 114 is also coupled in parallel to the diodes 108, 110 and the resonator 101. A supply voltage V_{DD} of the VCO 100 is further applied to the second electrical circuit 114.

Finally, the VCO 100 comprises a third electrical circuit 119, coupled in parallel to the resonator 101, to the first electrical circuit 108, 110 and to the second electrical circuit 114, presenting to the other elements of the VCO 100 a negative electrical resistor, which is to say a complex impedance whose real part has a strictly negative value. In the example in FIG. 1, this third electrical circuit 119 comprises a differential pair made by two field effect transistors of the MOS type 102, 104 mounted in differential. The third electrical circuit 119 also comprises a capacitor 103, as well as two current polarisation sources 105. The capacitor 103 ensures that the differential pair has a gain of less than 1 at low frequency, thus avoiding that it behaves like a switch due to a positive reaction effect to its continuous frequency, and thus avoids the differential pair blocking.

One embodiment of the second electrical circuit 114 is shown in FIG. 2. This second circuit 114 comprises two transistors MOS 113a that are identical to one another, and two other transistors MOS 113b also identical to one another. These four transistors are polarised by two current sources 115. The second electrical circuit 114 further comprises an inductance 117 of value L. Finally, inputs 118 permit the second circuit 114 to be coupled in parallel to the other elements of the VCO 100.

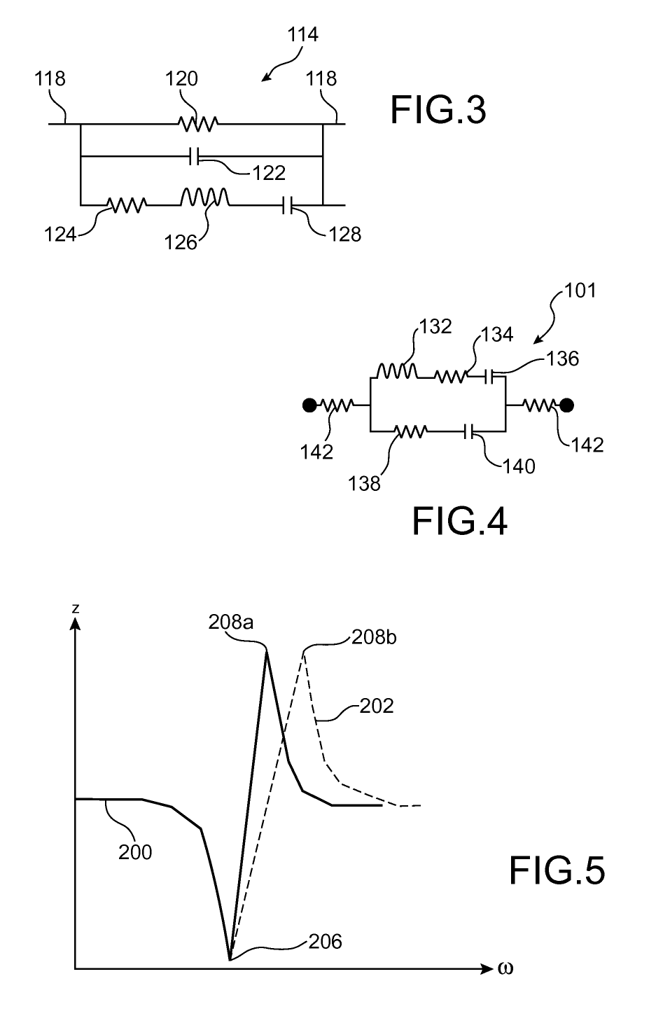

An equivalent circuit of the second electrical circuit 114 is shown in FIG. 3. This equivalent circuit comprises a first resistive element 120 whose electrical resistor is equal to the drain-source resistor Rds1 of the transistors 113a. This first resistive element 120 is coupled in parallel to a first capacitive element 122 whose electrical capacity is equivalent to the gate-source capacity Cgs2 of the transistors 113b. The first capacitive element 122 is coupled in parallel to three other elements that are coupled to one another in series:
a second resistive element 124 has a negative electrical resistor equal to −1/(gm²Rds2), wherein gm is the transconductance of the transistors 113a and 113b and Rds2 the drain-source resistor of the transistors 113b,
an inductive element 126 with a value equal to −Cgs1/gm², where Cgs1 is here the gate-source capacity of the transistors 113a,
a second capacitive element 128 with a negative electrical capacity equal to −L.gm².

It may be seen therefore that the complex impedance of the second electrical circuit 114 is especially formed by a real negative part equal to −1/(gm²Rds2) and an imaginary part equal to

$$\frac{- j}{{C}_{2} ω} ,$$

where c₂=−L.gm², wherein the impedances of the first resistive element 120 and the first capacitive element 122 may be negligible with respect to the impedances of the second resistive element 124 and the second capacitive element 128. Furthermore, given that the values of the impedances of the inductive element 126 and the second capacitive element 128 depend on the value of gm, this value of gm is therefore selected so that a parasite resonance between the inductive element 126 and the second capacitive element 128 may be avoided, while having a complex impedance on the second electrical circuit 114 adapted to the VCO 100.

The frequency response of the acoustic wave resonator 101 alone may be modelled in the first degree by an equivalent circuit shown in FIG. 4. This circuit comprises an inductance Lm 132 coupled in series to a resistor Rm 134 and a capacity Cm 136, wherein these three elements are coupled in parallel to two elements coupled to one another in series: a resistor Ro 138 and a capacity Co 140. These five elements are coupled in series with two resistors Rs 142 representing the electrical losses of the resonator 101.

The inductance Lm and the electrical capacity Cm represent the acoustic effect itself of the resonator 101. The series resonance frequency ωᵣ of the resonator 101 is expressed by the equation:

$${ω}_{r}^{2} = \frac{1}{LmCm} \qquad ( 1 )$$

The capacity Co represents the dielectric effect of the resonator 101, and intervenes in the calculation of the anti-resonance frequency ωₐ of the resonator 101 according to the expression:

$${ω}_{a}^{2} = \frac{Co + Cm}{LmCmCo} \qquad ( 2 )$$

The overall impedance Z of the resonator 101 is in this case equivalent to:

$$Z = \frac{1}{{jω}_{r} Φ} \qquad ( 3 )$$

where:

$$Φ = \frac{LmCmCo {ω}^{2} - Co - Cm}{LmCm {ω}^{2} - 1} \qquad ( 4 )$$

and ω: frequency of the resonator 101

Φ is here expressed neglecting the losses corresponding to the resistors Rs.

The resistor Ro represents the dielectric losses and Rm the acoustic losses. It is thus possible to define the quality coefficient Qᵣ of the resonator 101 at the series resonance frequency ωᵣ by the following expression:

Qᵣ=Qₘ (5)

where Qm: quality coefficient specific to the acoustic branch of the equivalent circuit of the resonator, dependent on the acoustic losses Rm.

The quality coefficient Qₐ of the resonator 101 at the anti-resonance frequency ωa is defined by the expression:

$$\frac{1}{{Q}_{a}} = \frac{1}{{Q}_{m}} + \frac{{C}_{m}}{{C}_{0}} \cdot \frac{1}{{Q}_{0}} \qquad ( 6 )$$

Qo is the quality coefficient specific to the dielectric branch of the model, dependent on the dielectric losses Ro.

The graph 200 illustrated in FIG. 5 represents the evolution of the impedance Z of the acoustic resonator 101 without the other elements of the VCO 100, according to the frequency ω of the resonator 101. This graph 200 comprises a lower peak 206 which corresponds to the series resonance frequency ωᵣ of the acoustic resonator 101 expressed by the equation (1) mentioned above. Furthermore, the graph 200 also comprises a higher peak 208a which corresponds to the anti-resonance frequency ωₐ of the acoustic resonator 101 expressed above by the equation (2).

The graph 202 illustrated in FIG. 5 represents the evolution of the impedance Z of the acoustic resonator 101 according to the frequency ω of the resonator 101 when it is coupled to the second electrical circuit 114 with a complex impedance whose imaginary part is equal to

$$\frac{- j}{{C}_{2} ω} ,$$

where C₂<0. The two graphs 200 and 202 comprise a same lower peak 206 indicating that the series resonance frequency ωᵣ remains unchanged with or without the circuit 114. On the other hand, it may be seen that the graph 202 has a higher peak 208b offset towards higher frequencies with respect to the peak 208a, translating the fact that the anti-resonance frequency has moved towards higher frequencies by coupling the electrical circuit 114 with the resonator 101. This new anti-resonance frequency ωₐ′ may in this case be expressed by the following equation:

$${ω}_{a}^{′2} = \frac{Co + Cm + {C}_{2}}{LmCm ( Co + {C}_{2} )} \qquad ( 7 )$$

where C₂: value of the negative electrical capacity, or imaginary part of the complex impedance, of the second electrical circuit 114 (where C₂=−L.gm² in the case of the example shown in FIG. 2).

In the first degree, the negative electrical capacity of the second electrical circuit 114 of the VCO 100 is presented in parallel to the dielectric capacity Co, to the capacity Cm and to the inductance Lm of the resonator 101, as well as to the positive variable electrical capacity formed by the two diodes 108, 110.

Whereas, given that the variation of the electrical capacity formed by the diodes 108, 110 in the VCO 100 brings the anti-resonance frequency towards the lower frequencies, the negative electrical capacity of the second electrical circuit 114 thus permits the range of possible anti-resonance frequencies to be increased, wherein this range is between a first configuration in which the equivalent electrical capacity of the diodes 108, 110 is nil (corresponding for example to the graph 202) and a second configuration in which the equivalent electrical capacity of the diodes 108, 110 is such that the anti-resonance frequency reaches a value substantially equal to the series resonance frequency.

This increase in the range of variation of the anti-resonance frequency of the VCO 100 is accompanied by a modification of the anti-resonance quality coefficient of the arrangement formed by the elements 101, 108, 110 and 114, which then take on the following value (at the anti-resonance frequency):

$$\frac{1}{{Q}_{a}} = \frac{1}{{Q}_{m}} + \frac{{C}_{m}}{{C}_{0} + {C}_{1} - Cn} \cdot \frac{1}{{Q}_{//}} \qquad ( 8 )$$

where C₁: equivalent electrical capacity of the diodes 108, 110;

Cn: absolute value of the negative electrical capacity of the second electrical circuit 114, which is to say Cn=|C₂|;

Q_{//}: sum of the weighted quality coefficients of the dielectric branch Qo of the acoustic resonator 101 and the variable electrical capacity (diodes) Qv, such that:

$${Q}_{//} = {Q}_{0} \cdot \frac{{R}_{V}}{{R}_{0} + {R}_{V}} + {Q}_{V} \cdot \frac{{R}_{0}}{{R}_{0} + {R}_{V}} \qquad ( 9 )$$

Rv represents the electrical losses of the diodes 108, 110.

The increasing factor of the quality coefficient Q_{//}, equal in the equation (8) to

$$\frac{{C}_{m}}{{C}_{0} + {C}_{1} - {C}_{N}} ,$$

is reduced by the presence of the negative electrical capacity Cn. Rigorously, the formulation of the quality coefficient Q_{//} should take into account the resistive losses of the second circuit 114. However, these resistive losses are negative and contribute to creating the oscillation condition. They should therefore not be taken into account, so that the analysis remains comparable with that of a VCO using a resonator without a negative electrical capacity.

In the embodiment of the second electrical circuit 114 previously described in relation to FIG. 2, naturally it has a negative electrical resistor, which is to say a complex impedance whose real part has a negative value, that generally is minimised where possible when this function is used. However, in the application for a VCO described here, this negative electrical resistor is on the contrary selected with a high value, in order to satisfy the oscillation conditions. If the negative electrical resistor of the second electrical circuit 114 is sufficient, which is to say that it permits the losses of the resonator 101 to be compensated, it is possible to make the VCO 100 without the third electrical circuit 119.

For example, for the VCO 100, by selecting a resonator 101 such that the anti-resonance quality coefficient of the resonator alone is equal to 600, and its initial frequency is 2.306 GHz, adding a second electrical circuit with a complex impedance whose imaginary part is equivalent to that of a negative electrical capacity of −0.7 pF takes the anti-resonance frequency to 2.43 GHz. The quality coefficient is then degraded to approximately 220. By then varying the value of the imaginary part of the complex impedance of the diodes 108, 110, equivalent to a positive electrical capacity, from 0 to 2.8 pF, whose intrinsic quality coefficient is 100, it may be seen that this covers a range of frequency variation greater than 160 MHz, with a quality coefficient which increases as it approaches the series resonance frequency. Such a variation range of 160 MHz corresponds to the variation ranges required for the current digital mobile communication systems.

The resonator with high quality coefficient, which is to say the BAW resonator 101 of the VCO 100, is characterised by a series resonance frequency and an anti-resonance frequency such that the frequential difference between these two frequencies depends on the physical characteristics of the resonator. For mobile communication systems, the high quality coefficient resonator is preferably a Bulk Acoustic Wave resonator (BAW), whose piezo-electrical material used may be aluminium nitride or any other piezo-electrical material suited to making such a high quality coefficient resonator. In one variant of the VCO 100, the resonator 101 may be a Surface Acoustic Wave resonator (SAW).

Making the VCO may lead to the integration of the high quality coefficient resonator according to several available microelectronic techniques, such as flip-chip, bonding, or even post-processing.

The second electrical circuit 114 previously described is made with transistors that are made using CMOS technology. However, these transistors may also be made using SOI, BiCMOS or even AsGa technology.

Furthermore, the variable electrical capacity created by the diodes 108, 110 may also be made using other components, for example switched capacities.

The displacement towards a higher value of the anti-resonance frequency of an acoustic wave resonator using an electrical circuit with a complex impedance whose imaginary part is equivalent to that of a negative electrical capacity, is the electrical equivalent of increasing the electromechanical coupling coefficient of the resonator. The impedance of the arrangement thus increases as well. These properties may be used to make selective filters with very wide band for RF frequencies. Indeed, the band width of a piezo-electrical resonator filter is directly dependent on this coupling coefficient. The coupling of the resonator to an electrical circuit with a negative electrical capacity allows filters to be created with insertion losses and rejection that are almost the same as those of classic filters, but whose band width may reach over 150 MHz (compared to approximately 60 MHz for the known filters).

The VCO 100 may for example be obtained by first making the different electronic elements such as the electrical circuits 114, 119 and the diodes 108 and 110 on a substrate, then making the resonator 101 and the connecter for example by wire-bonding or flip-chip, next to or on these electronic elements.

1. Electrical resonator device, capable of operating at variable frequency ω, comprising at:
an acoustic wave resonator,
a first electrical circuit coupled in parallel to the resonator with an adjustable complex impedance whose imaginary part is equal to
$$\frac{- j}{{C}_{1} ω} ,$$
where C₁≧0,
a second electrical circuit coupled in parallel to the resonator and the first electrical circuit, with a complex impedance whose imaginary part is equivalent to a negative electrical capacity and equal to
$$\frac{- j}{{C}_{2} ω} ,$$
where C₂<0,
ω is the operating frequency of the device.

2. The device of claim 1, wherein the complex impedance of the second electrical circuit comprises a real part whose value is strictly negative.

3. The device of claim 1, wherein the second electrical circuit comprises a plurality of field effect transistors coupled to an inductive component.

4. The device of claim 1, wherein the first electrical circuit comprises at least one diode of the varicap type.

5. The device of claim 1, wherein the first electrical circuit comprises at least one switched capacity.

6. The device of claim 1, wherein the resonator is of the Bulk Acoustic Wave or Surface Acoustic Wave type.

7. The device of claim 1, further comprising a third electrical circuit coupled in parallel to the resonator, to the first and the second electrical circuits, and with a complex impedance whose real part has a strictly negative value.

8. The device of claim 7, wherein the third electrical circuit comprises at least one differential pair formed by at least two field effect transistors.

9. Voltage controlled oscillator comprising at least the device of claim 1.

10. Electronic filter comprising at least the device of claim 1.
